(19) United States
(12) Patent Application Publication
(10) Pub. No.: US 2009/0314635 A1
(43) Pub. Date: Dec. 24, 2009

(54) PLASMA PROCESSING APPARATUS, PLASMA PROCESSING METHOD, AND ORGANIC ELECTRON DEVICE

(75) Inventors: Kazuki MOYAMA, Amagasaki City (JP); Tomohiko EDURA, Sendai City (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/407,933

(22) Filed: Mar. 20, 2009

(30) Foreign Application Priority Data
Jun. 24, 2008 (JP) 2008-164733

(51) Int. Cl. C23C 14/34; C23F 1/08

(52) U.S. Cl. 204/192.32; 156/345.48; 204/298.31

(57) ABSTRACT

An organic film and a metal electrode (a cathode film) are formed on an indium tin oxide (ITO) of a substrate. The plasma processing apparatus supplies at least one of a predetermined processing gas for chemically reacting with the organic film and a predetermined inert gas for sputtering the organic film from a gas supply source into a processing container, wherein the metal electrode is used as a mask. The plasma processing gas also supplies microwaves from a microwave generator as energy for exciting the at least one of the predetermined processing gas and the predetermined inert gas. The plasma processing apparatus generates plasma from the at least one of the predetermined processing gas and the predetermined inert gas supplied to the processing container by using electric field energy of the microwaves, and etches the organic film by using the generated plasma.

### CROSS-REFERENCE TO RELATED PATENT APPLICATIONS

This application claims the benefit of Japanese Patent Application No. 2008-164733, filed on Jun. 24, 2008, in the Japan Patent Office, the disclosure of which is incorporated herein in its entirety by reference.

### BACKGROUND OF THE INVENTION

1. Field of the Invention

The present invention relates to a plasma processing apparatus and a plasma processing method, and more particularly, to a plasma processing apparatus and a plasma processing method for etching an organic layer formed on a substrate.

2. Description of the Related Art

An organic electroluminescent (EL) device is formed by sequentially stacking an organic layer and a cathode layer on an anode layer patterned on a glass substrate. When a voltage of several volts is externally applied between an anode and a cathode between which an organic film is sandwiched, electrons are injected into the organic layer from the cathode and holes are injected into the organic layer from the anode. Thus, organic molecules are excited according to the injection of the electrons and holes, but when the electrons and holes are recombined, the excited organic molecules return back to a ground energy state. During such a process, an energy is released as light.

In order to enable the organic EL device to self-emit light according to the above principle, wiring for applying a voltage from a power supply source to an electrode is required. Accordingly, after forming the organic layer, the organic film is patterned for forming the wiring. In this case, since the organic film is etched by using the cathode layer as a mask, an etching selectivity between the organic film and the cathode layer is important so as to prevent etching of the cathode layer while etching the organic film as much as possible. Also, it is required to improve throughput by increasing an etching rate of the organic film.

Accordingly, various suggestions for improving the etching rate have been made, such as in Japanese Laid-Open Patent Publication No. 2007-180358 (hereinafter, referred to as a cited reference 1). Referring to the cited reference 1, in a parallel plate type plasma processing apparatus, radio frequency power for forming plasma and radio frequency power for feeding ions are separately applied to a lower electrode on which an object to be processed is disposed. In this case, since plasma is generated near a wafer, an etching rate may be increased. Also, by independently controlling a plasma generating function and an ion feeding function required for plasma etching, highly minute processing becomes possible.

However, in the cited reference 1, since the radio frequency power for feeding ions is applied to the lower electrode, not only an etching rate of an organic film but also an etching rate of a cathode film are increased when the organic film is etched by simply using the cathode film as a mask. Specifically, when the cathode film is formed of silver (Ag), the cathode film may be etched faster than the organic film.

### SUMMARY OF THE INVENTION

To solve the above and/or other problems, the present invention provides a plasma processing apparatus and a plasma processing method, which improve an etching rate of an organic film and an etching selectivity of the organic film with respect to a cathode film by using a predetermined processing gas or a predetermined inert gas.

According to an aspect of the present invention, there is provided a plasma processing apparatus including a processing container for internally performing an etching process on an organic film on a substrate using plasma, a gas supply source for supplying at least one of a predetermined processing gas for chemically reacting with the organic film and a predetermined inert gas for sputtering the organic film into the processing container, wherein a cathode film on the organic film is used as a mask; and an energy source for supplying energy for generating plasma from the at least one of the predetermined processing gas and the predetermined inert gas supplied from the gas supply source.

According to the plasma processing apparatus, the predetermined processing gas for chemically reacting with the organic film or the predetermined inert gas for sputtering the organic film is supplied into the processing container by using the cathode film as a mask. The predetermined processing gas is a gas able to etch the organic film via a chemical reaction. For example, nitrogen gas (N₂) or oxygen gas (O₂) may be introduced as the predetermined processing gas.

Specifically, the nitrogen gas does not corrode the cathode film, and chemically etches the organic film by chemically reacting with the organic film. The organic film is chemically etched as N radicals in the plasma generated from the nitrogen gas mainly chemically react with CₓH_{y} of the organic film. Hydrogen cyanide (HCN), which is a generated reaction product, is turned into gas, and exhausted outside the processing container. Meanwhile, when the nitrogen gas chemically reacts with the cathode film, a nitride is generated, and the nitride is accumulated on the cathode film. As a result, an etching selectivity of the organic film with respect to the cathode film operating as a mask is increased, so that an etching process of a desired patterning may be performed on the organic film, without excessively etching the cathode film.

The predetermined inert gas is a gas able to etch the organic film via sputtering, and for example, helium gas, neon gas, argon gas, krypton gas, or xenon gas may be introduced as the predetermined inert gas. Specifically, the predetermined inert gas may be a light element such as helium gas. Accordingly, the organic film may be physically etched without damaging a cathode during sputtering. Specifically, by combining the predetermined inert gas such as the light element and the predetermined processing gas such as the nitrogen gas, an etching rate of the organic film is improved and an etching selectivity of the organic film with respect to the cathode film is improved with regard to both the chemical etching and physical etching.

Radio frequency power in a range of about 0.125 to about 0.5 W/cm² may be applied to a susceptor on which the substrate is disposed. The energy source may apply microwaves into the processing container, wherein a pressure of the processing container is maintained in a range of 5 to 20 mTorr.

Accordingly, by setting process conditions for promoting generation and diffusion of the plasma, the etching rate of the organic film and the etching selectivity of the organic film with respect to the cathode film may be improved.

According to another aspect of the present invention, there is provided a plasma processing method including supplying at least one of a predetermined processing gas for chemically reacting with an organic film and a predetermined inert gas for sputtering the organic film to a processing container, wherein a cathode film on the organic film formed on a substrate is used as a mask, supplying energy for exciting the at least one of the predetermined processing gas and the predetermined inert gas supplied to the processing container, and generating plasma from the at least one of the predetermined processing gas and the predetermined inert gas via the supplied energy, and etching the organic film by using the generated plasma.

According to another aspect of the present invention, there is provided an organic electronic device, wherein wiring connected to electrodes are formed on a patterned portion of an organic film etched by using the plasma processing apparatus of above.

According to the organic electronic device, productivity of the organic electronic device may be improved by increasing the etching rate of the organic film. Also, by increasing the etching selectivity of the organic film with respect to the cathode film, etching of the organic film may be accelerated by suppressing etching of a cathode layer (a metal electrode).

### BRIEF DESCRIPTION OF THE DRAWINGS

The above and other features and advantages of the present invention will become more apparent by describing in detail exemplary embodiments thereof with reference to the attached drawings in which:

FIG. 1 is a flowchart illustrating processes of manufacturing an organic electroluminescent (EL) electronic device, according to an embodiment of the present invention;

FIG. 2 is a pattern diagram of a cluster type substrate processing system according to the embodiment;

FIG. 3 is a diagram illustrating an organic EL electronic device manufactured according to the embodiment;

FIG. 4 is a longitudinal cross-sectional view of a radial line slot antenna (RLSA) plasma processing apparatus according to the embodiment;

FIGS. 5(a) and 5(b) are graphs showing bias dependency according to a type of gas according to the embodiment;

FIGS. 6(a) and 6(b) are graphs showing pressure dependency according to a type of gas according to the embodiment;

FIG. 7(a) is a diagram for describing physical etching of an organic film and a cathode;

FIG. 7(b) is a diagram for describing chemical etching of an organic film and a cathode, according to an embodiment;

FIG. 8 is SEM photographic images showing etching states of an organic film and a cathode according to a type of gas, according to an embodiment;

FIG. 9 is a table showing ionized energy of an inert gas, according to an embodiment; and

FIG. 10 is a longitudinal cross-sectional view showing a cellular microwave excitation plasma (CMEP) plasma processing apparatus according to a modified embodiment.

### DETAILED DESCRIPTION OF THE INVENTION

Hereinafter, the present invention will be described in detail by explaining exemplary embodiments of the invention with reference to the attached drawings. In the following descriptions and attached drawings, like reference numerals denote like elements that have the same structure and functions, so as to omit overlapping descriptions. Also, 1 mTorr is equal to (10⁻³×101325/760) Pa and 1 sccm is equal to (10⁻⁶/60) m³/sec.

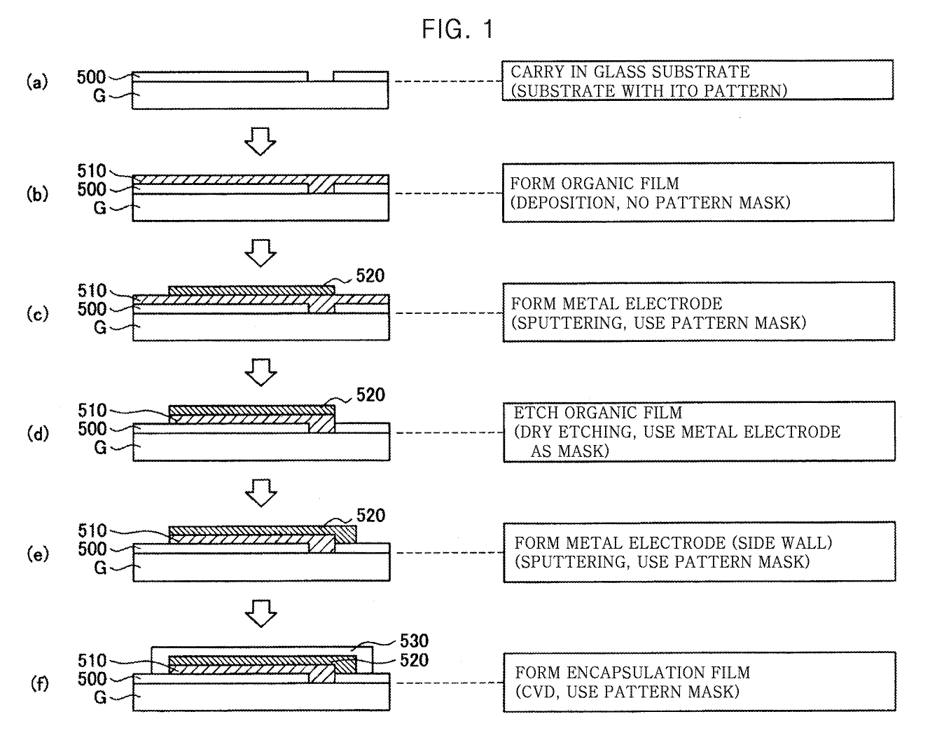

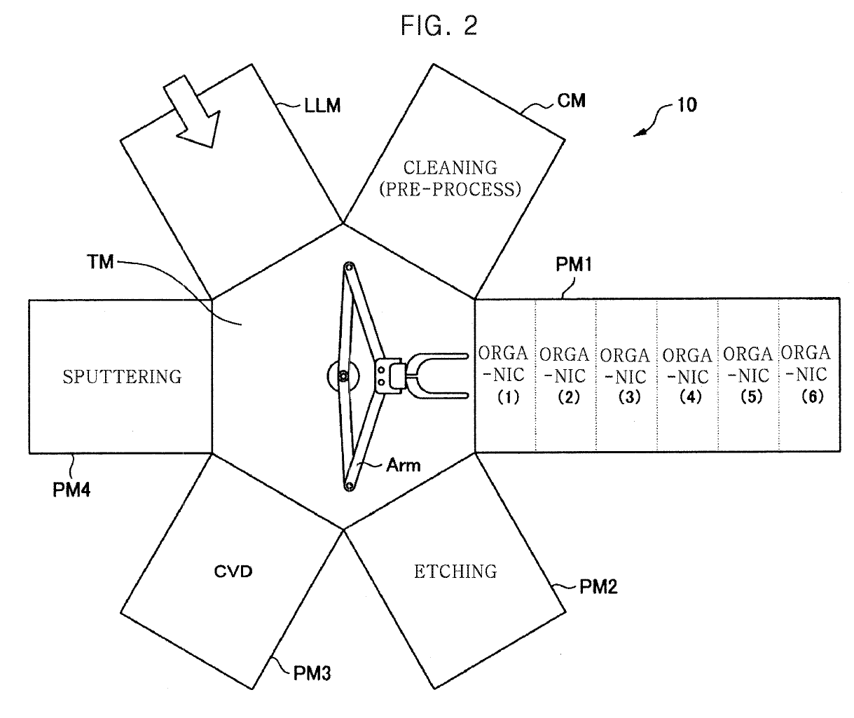

First, an embodiment of the present invention will now be described with reference to FIGS. 1 and 2. FIG. 1 is a flowchart illustrating processes of manufacturing an organic electroluminescent (EL) electronic device, according to an embodiment. FIG. 2 is a mimetic diagram of a cluster type substrate processing system 10 for performing each process of FIG. 1.

As illustrated in FIG. 1(a), a glass substrate (hereinafter referred to as a substrate G) is carried into an organic film forming apparatus. An indium tin oxide (ITO) 500, which operates as an anode, is pre-patterned on the substrate G. As illustrated in FIG. 2, the substrate G is cleaned in a cleaning module CM after it is received from a load lock module (LLM), and then carried into an organic film forming apparatus PM1.

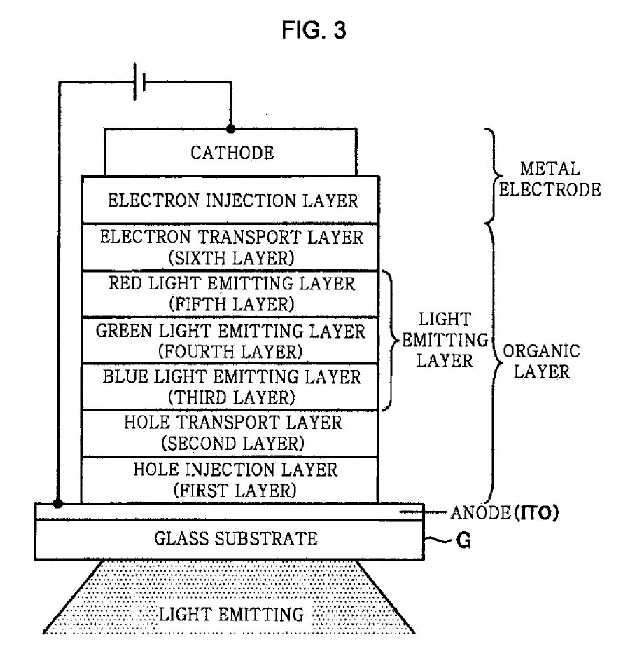

As illustrated in FIG. 1(b), the organic film forming apparatus PM1 continuously forms an organic film 510 having 6 layers on the ITO 500 via a deposition method. In detail, as illustrated in FIG. 3, a hole injection layer (a first layer), a hole transport layer (a second layer), a blue light emitting layer (a third layer), a green light emitting layer (a fourth layer), a red light emitting layer (a fifth layer), and an electron transport layer (a sixth layer) are formed on the ITO 500.

Then, the substrate G is conveyed to a process module PM4. As illustrated in FIG. 1(c), in the process module PM4, an electron injection layer is formed via sputtering, and then a silver (Ag) cathode film (a metal electrode 520) is formed by using a pattern mask. Next, the substrate G is conveyed to a process module PM2, and then as illustrated in FIG. 1(d), an organic layer is dry-etched in the process module PM2 by using the metal electrode 520 as a mask.

Then, the substrate G is carried again into the process module PM4. As illustrated in FIG. 1(e), the processing module PM4 forms a wiring portion connecting electrodes on a patterned portion of the organic film 510 etched in the previous process, via sputtering using a pattern mask. Next, the substrate G is conveyed to a process module PM3, and as illustrated in FIG. 1(f), an encapsulation film 530 is formed via a chemical vapor deposition (CVD) in the process module PM3. The encapsulation film 530 protects the organic EL electronic device from external moisture or oxygen.

The organic EL electronic device has a structure wherein the organic film 510 is disposed between an anode (ITO 500) and a cathode (metal electrode 520). When a voltage of several volts is externally applied between the anode and the cathode, electrons are injected into the organic film 510 from the metal electrode 520, and holes are injected into the organic film 510 from the ITO 500. Organic molecules are excited by the injection of the electrons and holes, but when the electrons and holes are recombined, the excited organic molecules return back to the ground state. The organic EL electronic device self-emits by using light emitted during this process.

[Etching Process of Organic Film]

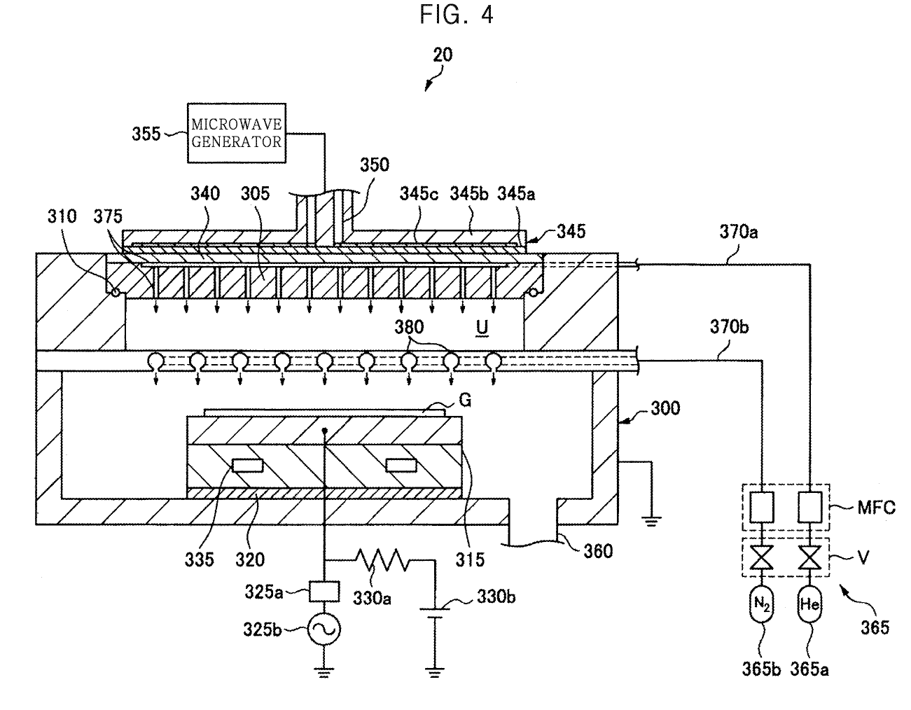

A dry-etching process of the organic film 510 illustrated in FIG. 1(d) will now be described in detail. The dry-etching process is performed by using a plasma processing apparatus 20 (installed in the process module PM2 of FIG. 2) illustrated in FIG. 4. The plasma processing apparatus 20 includes a radial line slot antenna (RLSA). The plasma processing apparatus 20 also includes a processing container 300 that has a cylindrical shape having an open top surface. A shower plate 305 is inserted into an opening of the open top surface. The processing container 300 and the shower plate 305 are sealed by an O-ring 310 that is installed between a stepped part of an inner wall of the processing container 300 and a bottom circumference part of the shower plate 305, and accordingly, a processing chamber U for performing a plasma process is formed. The processing container 300 is formed of, for example, a metal such as aluminum, and the shower plate 305 is formed of, for example, a metal such as aluminum or a dielectric substance and is electrically grounded.

A susceptor (loading table) 315, on which a wafer W is placed, is installed at a bottom part of the processing container 300 via an insulator 320. A radio frequency power supply source 325b is connected to the susceptor 315 via a matcher 325a, and a predetermined bias voltage is applied into the processing container 300 by radio frequency power output from the radio frequency power supply source 325b. Also, the susceptor 315 is connected to a high voltage direct current power supply source 330b via a coil 330a, and electrostatically absorbs the substrate G by using a direct current voltage output from the high voltage direct current power supply source 330b. Also, a cooling jacket 335 for supplying cooling water is placed inside the susceptor 315 so as to cool the wafer W.

A top of the shower plate 305 is covered by a cover plate 340. An RLSA 345 is formed on a top surface of the cover plate 340. The RLSA 345 includes a slot plate 345a having a disk shape and including a plurality of slots (not shown), an antenna body 345b having a disk shape and holding the slot plate 345a, and a wavelength-shortening plate 345c placed between the slot plate 345a and the antenna body 345b and formed of a dielectric substance such as alumina (Al₂O₃). A microwave generator 355 is externally installed to the RLSA 345 via a coaxial waveguide 350.

A vacuum pump (not shown) is attached to the processing container 300, and a gas inside the processing container 300 is exhausted via the gas exhaust pipe 360, thereby decompressing the processing chamber U to a desired vacuum degree.

A gas supply source 365 includes a plurality of valves V, a plurality of mass flow controllers MFC, a helium (He) gas supply source 354a, and a nitrogen (N₂) gas supply source 365b. The gas supply source 365 controls opening and closing of each of the valves V and an opening degree of each of the mass flow controllers MFC, so as to supply a gas of a desired concentration into the processing container 300.

As such, helium gas is supplied to an upper part of the processing chamber U from a gas supplying pipe 375 penetrating the shower plate 305, via a first flow path 370a, and nitrogen gas is supplied from an integrated gas pipe 380 via a second flow path 370b to a part of the processing chamber U in an area lower than an area where the helium gas is supplied. Accordingly, the helium gas and the nitrogen gas in the processing chamber U are dissociated and ionized by microwaves incident inside the processing chamber U from the microwave generator 355 via the slots and shower plate 305, thereby generating plasma. Helium ions (H⁺) in the plasma attack the organic film 510, and nitrogen ions (N⁺) or nitrogen radicals (H⁺) in the plasma chemically react with the organic film 510, and thus the organic film 510 is physically and chemically etched. A reaction product, i.e. hydrogen cyanide (HCN) turns into a gas and exhausted via a gas exhaust pipe 419.

[Etching Rate and Etching Selectivity]

According to the plasma processing apparatus 20 of the present embodiment, radio frequency power for feeding ions is applied to a susceptor 411 from a radio frequency power supply source 412b as described above, thereby increasing a physical etching rate using helium ions (He⁺). Accordingly, not only an etching rate of the organic film 510, but also an etching rate of the metal electrode 520 operating as a mask may increase. Consequently, it is important to specify process conditions in such a way that the etching rate of the organic film 510 is increased while the metal electrode 520 is not etched more than required.

[Physical Etching: Bias Power Dependency]

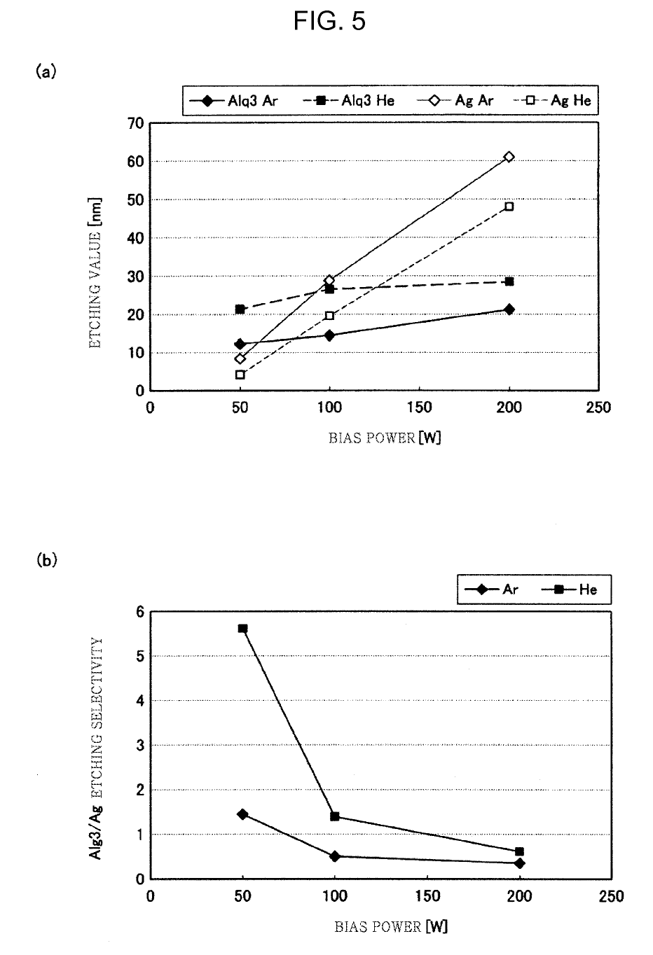

The inventor selected silver as an example of a material for forming the metal electrode 520, and selected Alq₃ (tris(8-hydroxyquinoline)aluminum: quinolinol aluminum complex) as an example of a material for forming the organic film 510, and thus compared bias dependency of each material according to a type of gas. The results of comparison are shown in FIGS. 5(a) and 5(b). Argon (Ar) gas and helium (He) gas were used as process gases.

Process conditions are as follows.

Microwave Power: 2 kW (about 0.52 W/cm²)

Top Plate Area: 3870 cm² (351 mmφ)

Bias Power (Radio Frequency Power): 50˜200 W (about 0.125˜about 0.5 W/cm²)

Internal Pressure of Processing Container: 5 mTorr

Gap between Susceptor and Top Plate: 110 mm

Susceptor Temperature: 20° C.

Processing Time: 60 s

For comparing the gases, a mixed gas of argon gas and nitrogen gas was supplied at a rate of Ar/N₂=120/30 sccm, and a mixed gas of helium gas and nitrogen gas was supplied at a rate of He/N₂=120/15 sccm. FIG. 5(a) shows bias power dependency of an etching value and FIG. 5(b) shows bias power dependency of an Alq₃/Ag etching selectivity.

According to FIG. 5(a), it is seen that an etching value is higher when Alq₃ is sputtered toward helium ions (He⁺) than when Alq₃ is sputtered toward argon ions (Ar⁺), when a bias power is in a range of 50 to 200 W (about 0.125 to about 0.5 W/cm²). Alternatively, under the same range of the bias power, an etching value is higher when silver (Ag) is sputtered toward the argon ions (Ar⁺) than when silver is sputtered toward the helium ions (He⁺). Accordingly, it is proven that the helium gas leads to a higher etching rate of an organic film and a higher etching selectivity of the organic film with respect to a cathode film than the argon gas, when the bias power is in the range of 50 to 200 W.

Then, according to FIG. 5(b), when the argon gas is used, Alq₃ is etched faster than silver when a bias power is equal to or lower than about 75 W (about 0.19 W/cm²), whereas when the helium gas is used, Alq₃ is etched faster than silver when a bias power is equal to or lower than about 150 W. Also, the helium gas has a higher etching selectivity of Alq₃ with respect to silver than the argon gas. Accordingly, it is proven that an etching selectivity of Alq₃ with respect to silver and an etching rate of Alq₃ are improved when the helium gas, which is an inert gas (a light element), is used as an etching gas, than when the argon gas that is heavier than the helium gas is used as the etching gas.

Also referring to FIG. 5(a), in case of the helium gas, the etching value of Alq₃ is higher than the etching value of silver when the bias power is in a range of 50 to 125 W (about 0.125 to about 0.313 W/cm²), and thus the bias power range of 50 to 125 W from among the entire bias power range of 50 to 200 W may be used as the process condition. Moreover, referring to FIG. 5(b), when the bias power is equal to or more than 150 W (about 0.375 W/cm²), the Alq₃/Ag etching selectivity of helium is lower than 1. Accordingly, even when the helium gas is used, the bias power may be equal to or lower than 150 W (about 0.375 W/cm²), and preferably equal to or lower than 125 W (about 0.313 W/cm²).

[Physical Etching: Pressure Dependency]

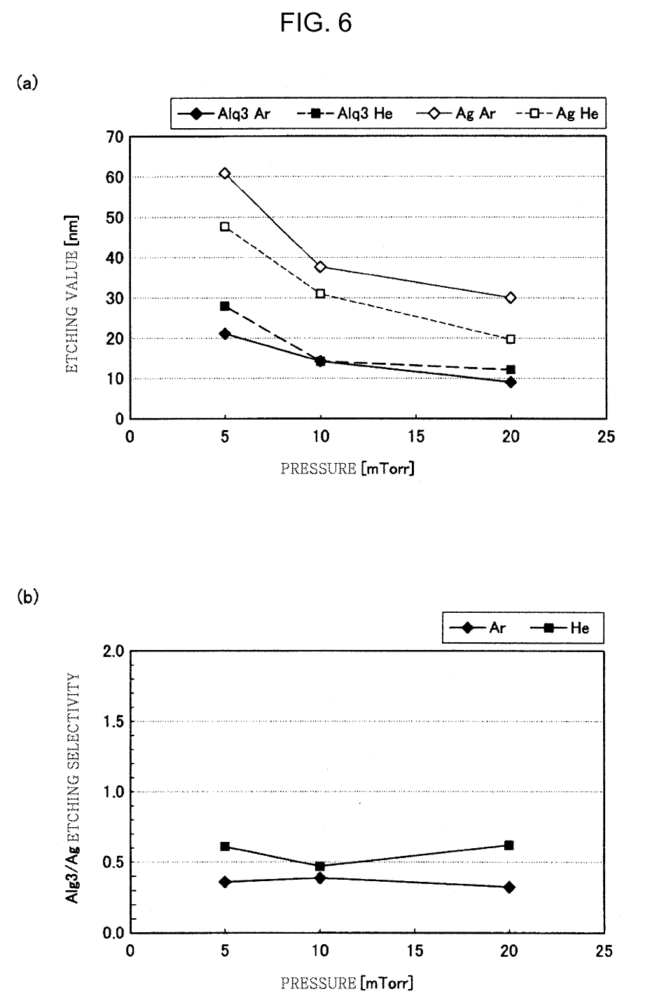

Next, the inventor compared pressure dependency of silver and Alq₃ according to a type of gas. The results of comparison are shown in FIGS. 6(a) and 6(b). Here, argon gas and helium gas were used.

Process conditions are as follows.

Microwave Power: 2 kW (about 0.52 W/cm²)

Bias Power: 200 W (about 0.50 W/cm²)

Internal Pressure of Processing Container: 5˜20 mTorr

Gap between Susceptor and Top Plate: 110 mm

Susceptor Temperature: 20° C.

Processing Time: 60 s

For comparing the gases, a mixed gas of argon gas and nitrogen gas was supplied at a rate of Ar/N₂=120/30 sccm, and a mixed gas of helium gas and nitrogen gas was supplied at a rate of He/N₂=120/15 sccm. FIG. 6(a) shows pressure dependency of an etching value, and FIG. 6(b) shows pressure dependency of Alq₃/Ag etching selectivity.

Referring to FIG. 6(a), when pressure is in a range of 5 to 20 mTorr, it is seen that an etching value is higher when silver attacks argon ions (Ar⁺) than when the silver attacks helium ions (He⁺). Alternatively, in the same pressure range, an etching value is higher when Alq₃ is sputtered toward the helium ions (He⁺) than when Alq₃ is sputtered toward the argon ions (Ar⁺). Accordingly, it is proven that an etching rate of an organic film and an etching selectivity of the organic film with respect to a cathode film are higher when the helium gas is used than when the argon gas is used.

Next, referring to FIG. 6(b), an etching selectivity of Alq₃ with respect to silver is higher when helium gas is used than when argon gas is used, when pressure is in a range of 5 to 20 mTorr. Accordingly, it is proven that when the pressure is in the range of 5 to 20 mTorr, the etching selectivity of Alq₃ with respect to silver and the etching rate of Alq₃ are improved when the helium gas, which is an inert gas (a light element), is used as an etching gas than when the argon gas that is heavier than the helium gas is used as the etching gas.

Specifically, in the plasma processing apparatus 20, plasma is generated in the vicinity of a dielectric window installed on the top of the processing container 300, by using energy of the microwaves. The generated plasma is diffused to a lower part of the processing container 300 toward the substrate G, and a desired process is performed on the substrate G by the plasma that reached the substrate G. Accordingly, when the pressure is in the range of 5 to 20 mTorr, a diffusion amount of the plasma that reached the substrate G without colliding with molecules inside the processing container 300 is relatively high compared to a case when the pressure is in a range other than 5 to 20 mTorr. Accordingly, when the pressure is in the range of 5 to 20 mTorr, plasma concentration right above the substrate G is increased. However, when the pressure is lower than 5 mTorr, a colliding power of ions that reached the substrate G without colliding with the molecules in the processing container 300 is increased, and thus damage to the substrate G is high. Accordingly, it is preferable to maintain the pressure of the processing container 300 in the range of 5 to 20 mTorr.

[Physical Etching]

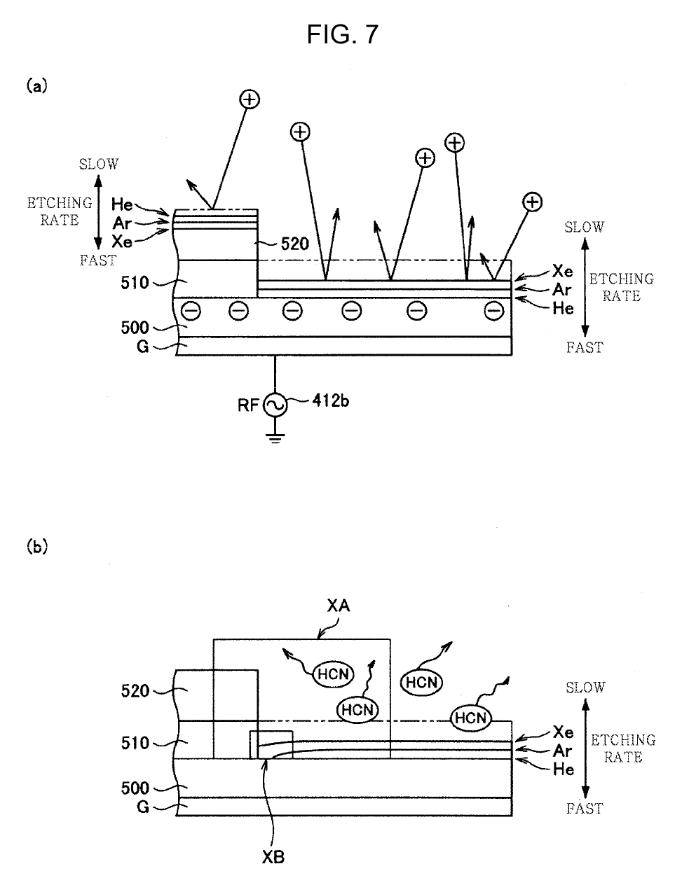

The above results are considered as follows in view of physical etching illustrated in FIG. 7(a). When a surface of the ITO 500 is negatively charged by radio frequency power applied from a radio frequency power supply source 412b, ions in diffused plasma accelerate toward the organic film 510 or the metal electrode 520 of silver, thereby colliding with films of the organic film 510 and the metal electrode 520. Accordingly, materials in the films are attacked and cracked, and thus the films are physically etched. In such physical etching, a heavier gas from among the supplied inert gases has larger colliding power toward the films, and thus an etching rate increases. As described above, in the metal electrode 520 made of silver, an etching rate when using the argon gas is higher than an etching rate when using the helium gas that is lighter than the argon gas.

On the contrary, in case of Alq₃ (organic film 510), an etching rate when using helium ions is higher than an etching rate when using argon ions. This is considered as follows in view of chemical etching.

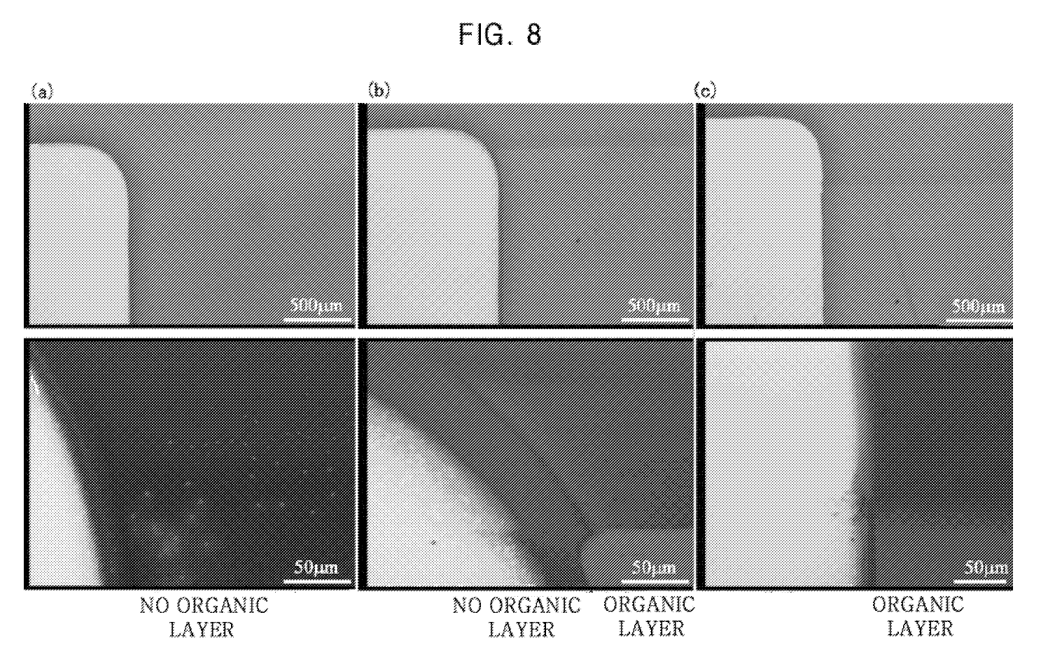

Chemical etching of the organic film 510 and the metal electrode 520 will now be described with reference to FIG. 8. FIG. 8 illustrates SEM photographic images showing etching states of the organic film 510 and the metal electrode 520 when the organic film 510 is etched by using 3 types of inert gases (helium gas, argon gas, and xenon gas).

Process conditions are as follows.
Microwave Power: 2 kW (about 0.52 W/cm²)
Bias Power: 0 kW (No Bias)
Internal Pressure of Processing Container: 20 mTorr
Gap between Susceptor and Top Plate: 110 mm
Processing Time: 60 s×5
Gas: Right Photograph of FIG. 8-Mixed Gas of Helium and Nitrogen He/N₂=70/35 sccm
   Center Photograph of FIG. 8—Mixed Gas of Argon and Nitrogen Ar/N₂=70/35 sccm
   Left Photograph of FIG. 8-Mixed Gas of Xenon and Nitrogen Xe/N₂=70/35 sccm
Susceptor Temperature Right Photograph of FIG. 8—more than 60° C.
   Center Photograph of FIG. 8—lower than 43° C.
   Left Photograph of FIG. 8—48-54° C.

Upper photographic images (3 sheets, 500 μm) of FIG. 8 show the vicinity of a portion XA of FIG. 7(b), a left side of each photographic image shows the metal electrode 520 stacked on the organic film 510, and a right side of each photographic image shows the organic film 510 etched according to each type of the gases. Lower photographic images (3 sheets, 50 μm) of FIG. 8 are enlarged diagrams of the vicinity of a portion XB of FIG. 7(b). In the right photographic images of FIG. 8, when a mixed gas of helium gas and nitrogen gas is used, the organic film 510 on the right side of the metal electrode 520 is etched almost entirely, and thus it can be considered that the organic film 510 disappears. In the center photographic images of FIG. 8, when a mixed gas of argon gas and nitrogen gas is used, an area that the organic film 510 does not exist in a right side of the metal electrode 520, but in a further right side, the organic film 510 can be seen. In the left photographic images of FIG. 8, when a mixed gas of xenon gas and nitrogen gas is used, the organic film 510 can be seen adjacent to a right side of the metal electrode 520. Referring to FIG. 8, in the case of the 3 types of inert gases that are mixed with nitrogen gas, it is seen that an etching rate of the organic film 510 increases in the order of helium gas, argon gas, and xenon gas. The results thereof are shown in FIG. 7(b).

[Chemical Etching]

The above results are considered as follows in view of the chemical etching shown in FIG. 7(b). For example, when nitrogen gas chemically reacts with the metal electrode 520, the nitrogen gas turns into silver nitride (AgN), and deposits on the metal electrode 520. Accordingly, the metal electrode 520 is not corroded by the nitrogen gas.

Meanwhile, the organic film 510 with the formula CₓH_{y} is etched by mainly chemically reacting with N radicals in plasma generated from the nitrogen gas, and the reaction product (HCN) that is accordingly generated turns into gas and is exhausted outside the processing container 300.

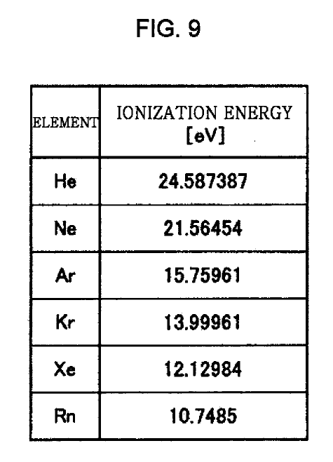

Specifically as shown in FIG. 8, the etching rate of the organic film 510 increases in the order of the helium gas, the argon gas, and the xenon gas, and thus in order to accelerate a chemical reaction with the organic film 510, it is better to use an inert gas having a light element from among inert gases. The reason for this is as follows. FIG. 9 is a table showing ionized energy of each element of inert gases. Referring to FIG. 9, as the element of the inert gas becomes lighter, the ionized energy increases. This shows that, when the element of the inert gas is light, energy required for separating an electron and a nucleus in an atom increases. That is, the atom of the helium gas from among the inert gases has the largest energy required to discharge electrons. In other words, when electrons are discharged from inert gases, energy of the electrons is the largest in the helium gas atom. Accordingly, when the helium gas is selected as an inert gas to be mixed with the nitrogen gas, plasma is generated from the helium gas by using energy of the microwaves, and electrons in the generated plasma most efficiently decompose the nitrogen gas, and thus the chemical reaction between the nitrogen gas and the organic film 510 is accelerated the most compared to the case of selecting the argon gas or xenon gas. Accordingly, referring to FIG. 9, when an element becomes lighter, electronic energy (electronic temperature) is increased, and thus the chemical reaction between the nitrogen gas and the organic film 510 is accelerated, thereby increasing the etching rate of the organic film 510. Alternatively, when an element becomes heavier, electronic energy (electronic temperature) is decreased, and thus the chemical reaction between the nitrogen gas and the organic film 510 is not accelerated, thereby deteriorating the etching rate of the organic film 510.

Accordingly, as illustrated in FIG. 7(b), the etching rate of the organic film 510 increases in the order of the helium gas, the argon gas, and the xenon gas from among the inert gases. According to the physical etching and the chemical etching described above, when the element of the inert gas mixed with the nitrogen gas is lighter, the etching rate of the organic film 510 and the etching selectivity of the organic film 510 with respect to the metal electrode 520 are increased.

As described above, in view of both the physical etching and the chemical etching, the etching selectivity of the organic film 510 with respect to the metal electrode 520 operating as a mask and the etching rate of the organic film 510 are improved by selecting at least one of a predetermined processing gas and a predetermined inert gas.

Also, at least one of helium gas, neon gas, argon gas, krypton gas, and xenon gas may be used as the predetermined inert gas. Specifically, as described above, a light element such as helium gas may be used. Since this element is light, damage of a film due to sputtering may be prevented, and since electronic energy (electronic temperature) of the light element is high, the etching rate of the organic film 510 and the etching selectivity of the organic film 510 with respect to the metal electrode 520 (cathode film) may be improved. Accordingly, the etching rate of the organic film 510 and the etching selectivity of the organic film 510 with respect to the metal electrode 520 may be increased in the order of helium gas, neon gas, argon gas, krypton gas, xenon gas, and radon gas.

Also, at least one of nitrogen gas and oxygen gas may be used as the predetermined processing gas. As described above, the nitrogen gas is preferable since the nitrogen gas does not corrode the metal electrode 520 (cathode film). When the oxygen gas is selected, the metal electrode 520 is oxidized and corrodes if silver (Ag) is used to form the metal electrode 520, and thus the metal electrode 520 need to be formed of aluminum (Al). When the metal electrode 520 is formed of aluminum, the reaction product generated by chemically reacting with oxygen is Al₂O₃, and thus Al₂O₃ is stably deposited on the aluminum.

In order to increase an etching rate of an organic film and an etching selectivity of the organic film with respect to a cathode film, microwaves may be supplied inside a processing container, wherein a pressure is maintained in a range of 5 to 20 mTorr, and radio frequency power in a range of about 0.125 to about 0.5 W/cm² may be applied to a susceptor on which a substrate is disposed.

As described above, according to the present embodiment, an etching rate of an organic film and an etching selectivity of the organic film with respect to a cathode film may be improved by supplying a predetermined processing gas or a predetermined inert gas into a processing container.

### Modified Embodiment

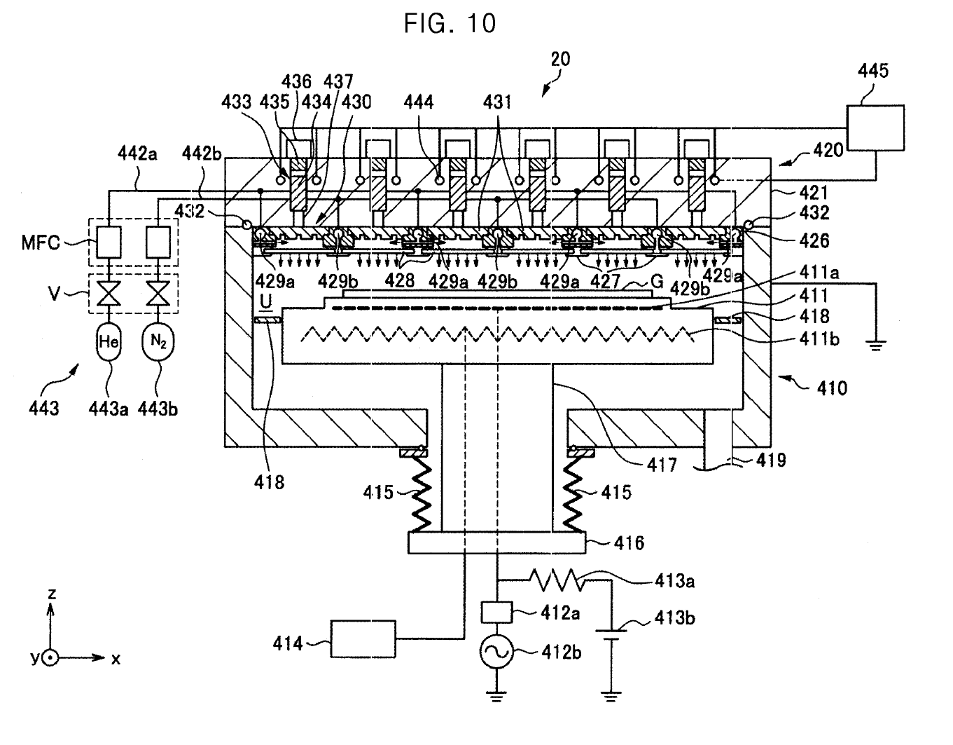

The dry-etching process of the organic film 510 shown in FIG. 1(d) is not only performed by using the RLSA plasma processing apparatus 20 of FIG. 4, but may also be performed by using a cellular microwave excitation plasma (CMEP) type plasma processing apparatus 20 illustrated in FIG. 10.

The CMEP type plasma processing apparatus 20 includes a processing container 410. A susceptor (loading table) 411 on which a substrate G is disposed is placed inside the processing container 410. A power feeder 411a and a heater 411b are formed inside the susceptor 411. The power feeder 411a is connected to the radio frequency power supply source 412b via a matcher 412a, applies a predetermined bias power into the processing container 410 according to radio frequency power output from the radio frequency power supply source 412b, is connected to a high voltage direct current power supply source 413b via a coil 413a, and electrostatically absorbs the substrate G via a direct current voltage output from the high voltage direct current power supply source 413b. The heater 411b is connected to an alternating current power supply source 414, and maintains the substrate G at a predetermined temperature via an alternating current voltage output from the alternating current power supply source 414.

A bottom surface of the processing container 410 is opened in a tube shape, and is sealed by a bellows 415 and an elevating plate 416. The susceptor 411 is elevated by being integrated with the elevating plate 416 and a tube body 417, and thus is adjusted to a height according to a processing process. A baffle plate 418 that adjusts a flow of gas of a processing chamber U is formed around the susceptor 411. Also, a vacuum pump (not shown) is attached to the processing chamber 410, and exhausts a gas inside the processing container 410 via a gas exhaust pipe 419 so as to decompress the processing chamber U down to a desired vacuum degree.

A covering object 420 includes a cover body 421, six waveguides 433, a slot antenna 430, and a dielectric window (a plurality of dielectric parts 431). A cross sectional form of each of the six waveguides 433 is a rectangular form. The six waveguides 433 are formed in parallel inside the cover body 421, and are filled with a dielectric member 434.

An area of a top plate of the covering object 420 is 1090 mm×866 mm, and an area of the susceptor 411 is 980 mm×790 mm. An area of the substrate G processed by the CMEP type plasma processing apparatus 20 may be, for example, 730 mm×920 mm.

A mobile unit 435 is inserted to an upper part of each of the waveguides 433 in such a way that the mobile unit 435 elevates freely, and an elevating structure 436 is formed on a top surface of the mobile unit 435. The elevating structure 436 elevates the mobile unit 435, and thus arbitrarily changes a height of the waveguide 433.

The slot antenna 430 includes a slot (opening) 437 at a bottom surface of each waveguide 433. The dielectric window includes 39 pieces of dielectric parts 431 having a tile shape. Each dielectric part 431 is formed of a dielectric material, such as quartz glass, AlN, Al₂O₃, sapphire, SiN, or ceramics. Each dielectric part 431 includes irregularities on a surface facing the substrate G.

The 39 pieces of dielectric parts 431 are supported by pillars 426 formed of a non-magnetic metal in a lattice shape. A plurality of gas pipes 428 are uniformly hung below bottom surfaces of the pillars 426 via a plurality of supporters 427, below an entire top surface. The gas pipes 428 are formed of a dielectric substance such as alumina.

A gas supply source 443 includes a plurality of valves V, a plurality of mass flow controllers MFC, a helium gas supply source 443a, and a nitrogen gas supply source 443b. The gas supply source 443 controls opening and closing of each valve V and also controls an opening degree of each mass flow controller MFC, thereby supplying a gas in a desired predetermined concentration into the processing container 410.

The helium gas supply source 443a supplies helium gas into the processing container 410 from a gas supplying pipe 429a via a first flow path 442a. The nitrogen gas supply source 443b supplies nitrogen gas into the processing container 410 from a gas supplying pipe 429b via a second flow path 442b. Cooling water supplied from a cooling water supply source 445 circulates through a cooling water pipe 444, and accordingly adjusts the temperature of the covering object 420.

According to the structure described above, microwaves output from a microwave generator (not shown) are supplied into the processing chamber U by penetrating each dielectric part 431 via each waveguide 433 and slot 437. According to an electric field energy of the microwaves, the helium gas and the nitrogen gas are dissociated and ionized, and thus plasma is generated. Helium ions (H⁺) in the generated plasma attach the organic film 510, and nitrogen ions (N⁺) or nitrogen radicals (H⁺) in the generated plasma chemically react with the organic film 510, and thus the organic film 510 is physically and chemically etched. The reaction product (HCN) turns into gas, and is exhausted via the gas exhaust pipe 419.

In the CMEP type plasma processing apparatus 20 according to the modified embodiment described above, an etching rate of an organic film and an etching selectivity of the organic film with respect to a cathode film are improved by supplying a predetermined processing as or a predetermined inert gas into the processing container 10.

An area of the substrate G may be equal to or larger than 730 mm×920 mm, for example, may have a G4.5 substrate size of 730 mm×920 mm (measurement in a chamber: 1000 mm×1190 mm) or a G5 substrate size of 1100 mm×1300 mm (measurement in a chamber: 1470 mm×1590 mm). Also, an object to be processed, where a device is formed, is not limited to the substrate G having the above area, and may be a silicon wafer with a diameter of 200 mm or 300 mm.

In the above embodiments, operations of components relate to each other, and thus may be rearranged as a series of operations while considering this relationship. In such a way, an embodiment of a plasma processing apparatus may be described as an embodiment of a plasma processing method. Also, an organic electronic device that includes wiring connected to electrodes on a patterned portion of an organic film that is etched via the plasma processing method may be manufactured.

As described above, according to the present invention, the etching rate of the organic film and the etching selectivity of the organic film with respect to the cathode film are improved by using a predetermined processing gas or a predetermined inert gas.

While this invention has been particularly shown and described with reference to exemplary embodiments thereof, it will be understood by those skilled in the art that various changes in form and details may be made therein without departing from the spirit and scope of the invention as defined by the appended claims.

For example, in the above embodiments, an etching rate and an etching selectivity are considered in view of both the physical etching and chemical etching. However, the present invention is not limited thereto, and for example, it is possible to improve an etching rate of an organic film only in view of the physical etching by supplying only a predetermined inert gas for sputtering the organic film into a processing container, and to select an inert gas capable of improving an etching selectivity of the organic film with respect to a cathode film.

Similarly, it is possible to improve an etching rate of an organic film only in view of the chemical etching by supplying only a predetermined processing gas to be chemically reacted with the organic film into a processing container, and to select a processing gas capable of improving an etching selectivity of the organic film with respect to a cathode film.

Also, an organic electronic device manufactured by using the plasma processing method according to the present invention is not limited to an organic EL device, and for example, may be an organic metal device that is formed via a metal organic chemical vapor deposition (MOCVD), wherein a film forming material mainly formed of a liquid organic metal is vaporized and decomposed on an object to be processed that is heated up to a range of 500 to 700° C., thereby forming a thin film on the object. Moreover, the organic electronic device manufactured by using the plasma processing method according to the present invention may be an organic device such as an organic transistor, an organic field effect transistor (FET), or an organic solar cell.

Also, an example of an organic EL device encapsulating a device by using a structure of an encapsulation film according to the present invention includes an organic light emitting diode.

The plasma processing apparatus according to the present invention is not limited to the CMEP type and RLSA type including a plurality of dielectric substances shown in the above embodiments, electron cyclotron resonance (ECR) type, and Metal Surfacewave Excitation Plasma (MSEP) type, and may be various plasma processing apparatuses, which etch an organic film formed on a substrate by using plasma wherein a cathode film on the organic film is used as a mask, such as an inductive coupling plasma (ICP) processing apparatus and a capacitive coupling plasma processing apparatus.

Accordingly, energy required to dissociate or ionize a gas supplied into a processing container is not limited to microwaves, and may be high frequency waves.

What is claimed is:

1. A plasma processing apparatus comprising:
a processing container in which an etching process on an organic film on a substrate is performed using plasma;
a gas supply source for supplying at least one of a predetermined processing gas for chemically reacting with the organic film and a predetermined inert gas for sputtering the organic film into the processing container, wherein a cathode film on the organic film is used as a mask; and
an energy source for supplying energy for generating plasma from the at least one of the predetermined processing gas and the predetermined inert gas supplied from the gas supply source.

2. The plasma processing apparatus of claim 1, wherein the gas supply source supplies at least one of nitrogen gas and oxygen gas as the predetermined processing gas.

3. The plasma processing apparatus of claim 1, wherein the gas supply source supplies at least one of helium gas, neon gas, argon gas, krypton gas, and xenon gas as the predetermined inert gas.

4. The plasma processing apparatus of claim 1, further comprising a radio frequency power supply source for supplying a radio frequency power in a range of about 0.125 to about 0.5 W/cm² to a susceptor on which the substrate is placed.

5. The plasma processing apparatus of claim 1, wherein the energy source supplies microwaves into the processing container, wherein a pressure of the processing container is maintained in a range of 5 to 20 mTorr.

6. A plasma processing method comprising:
supplying at least one of a predetermined processing gas for chemically reacting with an organic film and a predetermined inert gas for sputtering the organic film to a processing container, wherein a cathode film on the organic film formed on a substrate is used as a mask;
supplying energy for exciting the at least one of the predetermined processing gas and the predetermined inert gas supplied to the processing container; and
generating plasma from the at least one of the predetermined processing gas and the predetermined inert gas via the supplied energy, and etching the organic film by using the generated plasma.

7. The plasma processing method of claim 6, wherein at least one of nitrogen gas and oxygen gas is introduced as the predetermined processing gas.

8. The plasma processing method of claim 6, wherein at least one of helium gas, neon gas, argon gas, krypton gas, and xenon gas is introduced as the predetermined inert gas.

9. An organic electronic device, wherein wiring connected to electrodes are formed on a patterned portion of an organic film etched by using the plasma processing apparatus of claim 1.
